(19) United States
(12) Patent Application Publication
(10) Pub. No.: US 2025/0343046 A1
(43) Pub. Date: Nov. 6, 2025

(54) METHOD FOR FORMING ELECTRODE FOR SEMICONDUCTOR DEVICES, AND ELECTRODE FOR SEMICONDUCTOR DEVICES

(71) Applicant: JUSUNG ENGINEERING CO., LTD., Gwangju-Si, Gyeonggi-Do (KR)

(72) Inventors: Young Woon KIM, Gwangju-Si, Gyeonggi-Do (KR); Chul Joo HWANG, Gwangju-Si, Gyeonggi-Do (KR); Seok Jin PARK, Gwangju-Si, Gyeonggi-Do (KR); Yoon Ju LEE, Gwangju-Si, Gyeonggi-Do (KR); Su Vin KIM, Gwangju-Si, Gyeonggi-Do (KR); Seung Min YEO, Gwangju-Si, Gyeonggi-Do (KR)

(21) Appl. No.: 18/864,529

(22) PCT Filed: May 9, 2023
(86) PCT No.: PCT/KR2023/006303

§ 371 Date: Jul. 8, 2025

(30) Foreign Application Priority Data
May 10, 2022 (KR) 10-2022-0057186
Sep. 29, 2022 (KR) 10-2022-0124685

(51) Int. Cl. H01L 21/285; C23C 16/02; C23C 16/06; C23C 16/56

(52) U.S. Cl. CPC H01L 21/28506; C23C 16/02; C23C 16/06; C23C 16/56

(57) ABSTRACT

An electrode forming method for a semiconductor device in accordance with exemplary embodiments includes preparing a substrate, injecting a precursor containing a low-resistance metal element onto the substrate, and forming a low-resistance metal thin film layer by injecting a gas containing hydrogen (H) or oxygen (O) onto the substrate. Therefore, in accordance with exemplary embodiments, it is possible to provide an electrode from which ligand impurities derived from a precursor containing a low-resistance metal element are removed. Therefore, it is possible to provide an electrode with low resistance.

### BACKGROUND

The present disclosure relates to an electrode forming method for a semiconductor device, and more particularly, to an electrode forming method for a semiconductor device and an electrode for the semiconductor device capable of improving characteristics.

In order to improve electrical characteristics of a semiconductor device such as a NAND flash, it is necessary to lower the resistance of electrodes.

In forming the electrodes of the semiconductor device, a forming method may be used in which a precursor containing a metal is injected and deposited on a substrate.

Meanwhile, the precursor used for forming the electrodes includes ligands of at least one of carbon (C), oxygen (O), and hydrogen (H). However, these ligands act as impurities that increase the resistance of the electrode, and thus, there is a limitation in that the electrical characteristics of the semiconductor device are degraded.

In addition, with the development of semiconductor technology, high-speed and high-integration of semiconductor devices are rapidly progressing, and accordingly, demands for miniaturization of patterns and high precision of pattern dimensions are increasing. However, the characteristics of a film quality of the electrode of the semiconductor device may be degraded depending on a lower film and an upper film, which may affect the operation of the semiconductor device. Accordingly, in recent years, research and development for improving the operation of semiconductor devices by manufacturing semiconductor devices with a three-dimensional structure have been continuously conducted.

During such a manufacturing process, a silicon film or silicon-containing film and electrodes constituting the semiconductor device are exposed to an etching gas during a patterning or planarization process. The etching gas may be a gas containing a halogen element. Representative halogen elements such as fluorine (F) or chlorine (Cl) may react with a surface of the silicon film or silicon-containing film. The silicon film or silicon-containing film may be etched when exposed to a deposition gas. In forming an insulating film, dielectric film, or metal film on the silicon or the silicon-containing film, when gas for depositing the aforementioned thin film contains halogen elements such as fluorine or chlorine, the silicon film or silicon-containing film as the lower film may be unintentionally etched by the halogen element such as fluorine or chlorine in the process of forming the thin film. When the silicon film or silicon-containing film is etched by the halogen element included in the deposition gas during a deposition process, the surface of the etched silicon film or silicon-containing film is damaged and the surface of the film becomes irregular. The upper film formed on the lower film having the irregular surface may have defects at an interface with the lower film and the irregular surface may negatively affect the formation of the upper film.

In order to prevent damage to the lower film that occurs during the deposition process, a barrier film may be formed for the purpose of preventing damage to the lower film without directly forming a deposition film on the silicon film or silicon-containing film. When the deposition film is to be used as an electrode of a semiconductor device, a titanium nitride (TiN) film may be formed on the silicon film or silicon-containing film as a barrier film.

The titanium nitride film as the barrier film prevents the halogen element generated when the electrode, which is a metal film to be formed later, is formed from damaging the silicon film or silicon-containing film, which is the lower film; however, a reaction gas for forming the titanium nitride film may also contain a halogen element. For example, titanium tetrachloride (TiCl₄) is generally used to form the titanium nitride film. Therefore, the titanium nitride film, which is the barrier film formed between the silicon film or silicon-containing film and the electrode, may damage the silicon film or silicon-containing film as the lower film during the formation process, and thus the surface of the silicon film or silicon-containing film may become irregular. When the electrode is formed on the titanium nitride film, which is the barrier film, the titanium nitride film may be damaged by the halogen element included in the deposition gas forming the electrode. Even if damage to the silicon film or silicon-containing film, which is the lower film, is reduced, the titanium nitride film itself, which is the barrier film, may be damaged, causing cracks to occur in the titanium nitride film or the titanium nitride film itself to be damaged.

### RELATED ART DOCUMENTS

### Patent Documents

Korean Patent No. 10-0942958

Korean Patent Application Publication No. 10-2011-0001487

### SUMMARY

The present disclosure provides an electrode forming method for a semiconductor device capable of lowering the resistance of the electrode.

The present disclosure also provides an electrode forming method for a semiconductor device capable of removing impurities.

The present disclosure further provides an electrode forming method for a semiconductor device and an electrode for the semiconductor device for reducing damage to a lower film occurring in a process of forming the electrode.

In accordance with an exemplary embodiment, an electrode forming method for a semiconductor device includes preparing a substrate, injecting a precursor containing a low-resistance metal element onto the substrate, and forming a low-resistance metal thin film layer by injecting a gas containing hydrogen (H) or oxygen (O) onto the substrate.

The injecting of the precursor and the forming of the low-resistance metal thin film layer may be sequentially performed a plurality of times.

The electrode forming method may further include exposing the substrate to first plasma to remove impurities adsorbed on the substrate after the injecting of the precursor and exposing the low-resistance metal thin film layer to second plasma to remove impurities after the forming of the low-resistance metal thin film layer, and the injecting of the precursor, the exposing to the first plasma, and the exposing to the second plasma may be sequentially performed a plurality of times.

The low-resistance metal element may include at least one of molybdenum (Mo), ruthenium (Ru), and copper (Cu).

The first plasma may be formed of plasma containing hydrogen (H) or plasma containing oxygen (O).

The second plasma may be formed of plasma containing hydrogen (H) or plasma containing oxygen (O).

The electrode forming method may further include forming a TiN thin film layer on the substrate, the forming of the TiN thin film layer may include injecting a source containing titanium (Ti) on the substrate and injecting a gas containing nitrogen (N) on the substrate, and the injecting of the precursor containing the low-resistance metal element, the forming of the low-resistance metal thin film layer, and the forming of the TiN thin film layer may be sequentially performed a plurality of times.

In the preparing of the substrate, a substrate having an upper surface on which a TiN thin film layer is formed may be prepared.

In accordance with another exemplary embodiment, an electrode forming method for a semiconductor device includes preparing a substrate, forming a first low-resistance metal thin film layer by injecting a source containing a first low-resistance metal element and injecting a gas containing hydrogen (H) or oxygen (O), and forming a second low-resistance metal thin film layer by injecting a source containing a second low-resistance metal element and injecting a gas containing hydrogen (H) or oxygen (O), and the forming of the first low-resistance metal thin film layer and the forming of the second low-resistance metal thin film layer are sequentially performed a plurality of times.

The first low-resistance metal element and the second low-resistance metal element may contain at least one of molybdenum (Mo), ruthenium (Ru), and copper (Cu).

The first low-resistance metal element and the second low-resistance metal element may contain the same metal element.

At least one of the first low-resistance metal element and the second low-resistance metal element may contain two or more of molybdenum (Mo), ruthenium (Ru), and copper (Cu).

The electrode forming method may further include forming a TiN thin film layer by injecting a source containing titanium (Ti) and injecting a reactant containing nitrogen (N), and the forming of the first low-resistance metal thin film layer, the forming of the second low-resistance metal thin film layer, and the forming of the TiN thin film layer may be sequentially and repeatedly performed.

In the preparing of the substrate, a substrate having an upper surface on which a TiN thin film layer is formed may be prepared.

In accordance with yet another exemplary embodiment, an electrode forming method for a semiconductor device includes preparing a substrate, injecting a liquid precursor containing a low-resistance metal element onto the substrate, and forming a low-resistance metal thin film layer by injecting a gas containing hydrogen (H) or oxygen (O) onto the substrate.

The injecting of the precursor and the forming of the low-resistance metal thin film layer may be sequentially performed a plurality of times.

The low-resistance metal element may include at least one of molybdenum (Mo), ruthenium (Ru), and copper (Cu).

In accordance with still another exemplary embodiment, an electrode forming method for a semiconductor device includes forming a ruthenium film or a ruthenium-containing film on a silicon film or silicon-containing film and forming a tungsten-containing film on the ruthenium film or the ruthenium-containing film.

A thickness of the ruthenium film or the ruthenium-containing film may be formed to be a thickness of 50% or less of a thickness of the tungsten-containing film. The ruthenium film or the ruthenium-containing film may be formed to be a thickness of approximately 5 Å to 50 Å.

The ruthenium film or ruthenium-containing film may be formed by an atomic layer deposition method.

The ruthenium film or ruthenium-containing film may be formed of an organic source containing ruthenium.

The tungsten-containing film may be formed of a tungsten halogen gas.

The electrode may be any one of an electrode of a memory device, a word line, a bit line, an electrode of a transistor, an electrode of a GaN semiconductor, and an electrode of a GaAs semiconductor.

The electrode forming method may further include prior to the forming of the ruthenium film or the ruthenium-containing film, removing oxides or impurities from a surface of the silicon film or silicon-containing film.

In accordance with yet still another exemplary embodiment, an electrode for a semiconductor device includes a silicon film or silicon-containing film, a ruthenium film or a ruthenium-containing film formed on the silicon film or silicon-containing film, and a tungsten-containing film formed on the ruthenium film or the ruthenium-containing film.

A thickness of the ruthenium film or the ruthenium-containing film may be formed to be a thickness of 50% or less of a thickness of the tungsten-containing film.

The ruthenium film or the ruthenium-containing film may be formed to be a thickness of approximately 5 Å to 50 Å.

The ruthenium film or ruthenium-containing film may be formed by an atomic layer deposition method.

The ruthenium film or ruthenium-containing film may be formed of an organic source containing ruthenium.

The tungsten-containing film may be formed of a tungsten halogen gas.

The electrode may be any one of an electrode of a memory device, a word line, a bit line, and an electrode of a transistor.

### BRIEF DESCRIPTION OF THE DRAWINGS

Exemplary embodiments can be understood in more detail from the following description taken in conjunction with the accompanying drawings, in which:

FIG. 1 is a view illustrating a state in which an electrode in accordance with an exemplary embodiment is formed on a substrate;

FIG. 2 is a conceptual diagram for describing a method for forming an electrode by a method in accordance with the exemplary embodiment;

FIGS. 3A, 3B, 3C, and 3D are a process diagram conceptually illustrating the method for forming an electrode by the method in accordance with the exemplary embodiment;

FIG. 4 is a view illustrating a state in which an electrode in accordance with another exemplary embodiment is formed on a substrate;

FIG. 5 is a conceptual diagram for describing a method for forming an electrode by a method in accordance with the other exemplary embodiment;

FIG. 6 is a view illustrating a state in which an electrode in accordance with a modified example of the exemplary embodiment is formed on a substrate;

FIG. 7 is a view illustrating a state in which an electrode in accordance with another modified example of the exemplary embodiment is formed on a substrate;

FIG. 8 is a view schematically illustrating a structure of a semiconductor device in accordance with yet another exemplary embodiment; and

FIGS. 9 to 11 exemplarily illustrate a method of forming the semiconductor device in accordance with the yet another exemplary embodiment.

### DETAILED DESCRIPTION OF EMBODIMENTS

Hereinafter, exemplary embodiments of the present disclosure will be described in more detail with reference to the accompanying drawings. However, the present disclosure is not limited to the exemplary embodiments disclosed below, but will be implemented in a variety of different forms. The present exemplary embodiment is only provided to allow the present disclosure to be complete, and to completely inform those skilled in the art of the scope of the disclosure. In order to describe exemplary embodiments of the present disclosure, the drawings may be exaggerated, and the same reference numerals in the drawings refer to the same components.

Embodiments of the present disclosure relate to a electrode forming method for a semiconductor device, and more particularly, to an electrode forming method for a semiconductor device to improve electrical characteristics. More specifically, embodiments of the present disclosure relate to an electrode forming method for a semiconductor device, including a method for forming a low-resistance metal thin film layer.

As a specific example, the semiconductor device may be a NAND flash, and the electrode may be a gate electrode of the NAND flash. Of course, the electrode formed by the method in accordance with embodiments is not limited to the gate electrode, and may be any one of various components requiring conductivity, for example, a word line of a NAND flash. In addition, the electrode formed by the method in accordance with the embodiments is not limited to the NAND flash, and may be applied to thin films requiring conductivity in various semiconductor devices.

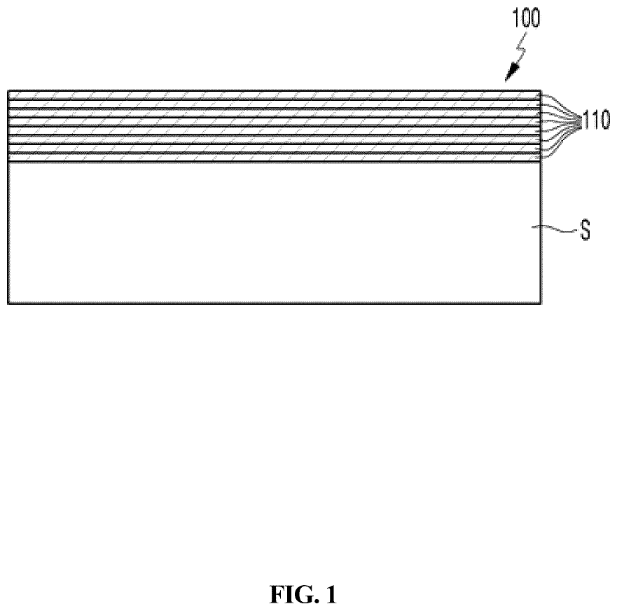

FIG. 1 is a view illustrating a state in which an electrode in accordance with an exemplary embodiment is formed on a substrate.

Referring to FIG. 1, an electrode 100 may be formed on a substrate S. Here, the substrate S may be a wafer, and may be any one of a Si wafer, a GaAs wafer, and a SiGe wafer.

The electrode 100 may be formed using a low-resistance metal element. Here, the low-resistance metal element may include at least one of molybdenum (Mo), ruthenium (Ru), and copper (Cu). Accordingly, the electrode may be a thin film formed using at least one of molybdenum (Mo), ruthenium (Ru), and copper (Cu), or a thin film containing at least one of molybdenum (Mo), ruthenium (Ru), and copper (Cu).

Hereinafter, a method for forming an electrode on a substrate by a method in accordance with the exemplary embodiment will be described with reference to FIGS. 1 to 3.

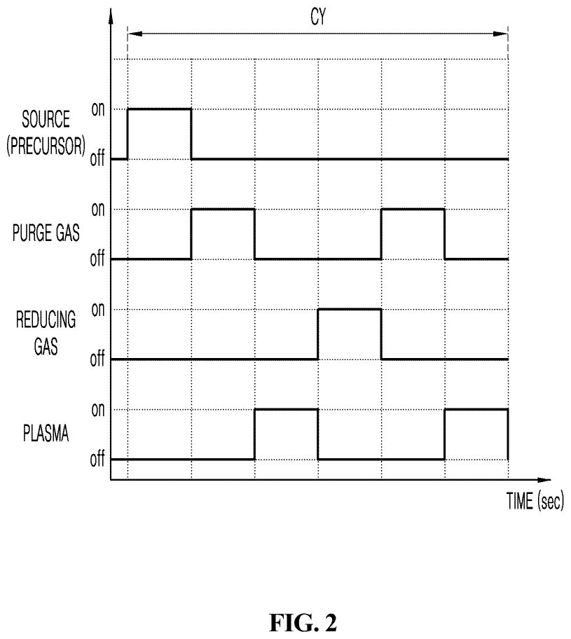

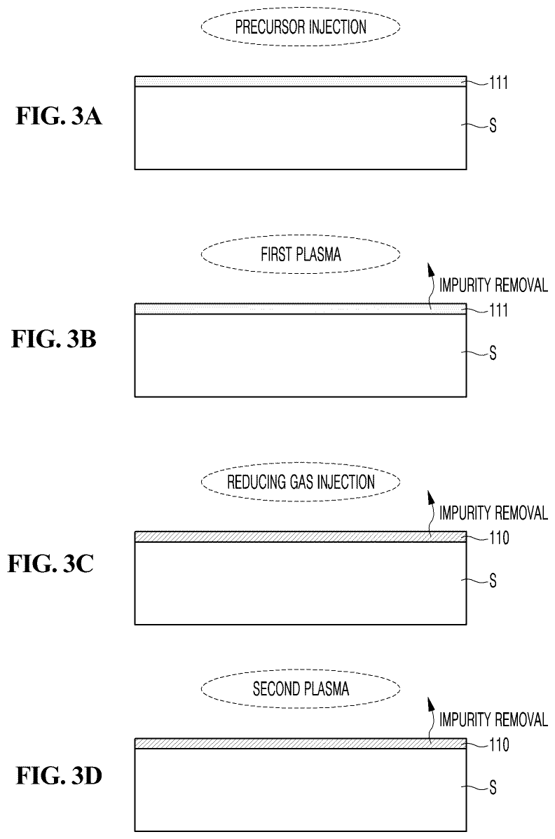

FIG. 2 is a conceptual diagram for describing the method for forming an electrode by the method in accordance with the exemplary embodiment. FIG. 3 is a process diagram conceptually illustrating the method for forming an electrode by the method in accordance with the exemplary embodiment.

In FIG. 2, “on” may mean that a raw material for deposition is injected or plasma is generated, and “off” may mean that raw material injection is stopped or finished or plasma is not generated.

Referring to FIG. 2, the method of forming the electrode 100 may include an operation of injecting a precursor containing a low-resistance metal element (precursor injecting operation) and an operation of forming low-resistance metal thin film layers 110 on the substrate S by injecting a reducing gas containing hydrogen (H) or oxygen (O) (reducing gas injecting operation).

In addition, the method of forming the electrode 100 may further include an operation of generating plasma using a gas containing hydrogen (H) or oxygen (O) after the precursor injecting operation is finished (first plasma generating operation) and an operation of generating plasma (hereinafter referred to as second plasma) using a gas containing hydrogen (H) or oxygen (O) to remove impurities from the low-resistance metal thin film layer 110 after the reducing gas injecting operation is finished (second plasma generating operation).

In addition, the method of forming the electrode 100 may further include an operation of injecting a purge gas between the precursor injecting operation and the first plasma generating operation (first purge operation) and an operation of injecting a purge gas between the reducing gas injecting operation and the second plasma generating operation (second purge operation).

That is, the method of forming the electrode 100 may include the precursor injecting operation, the purge gas injecting operation (first purge operation), the first plasma generating operation, the reducing gas injecting operation, the purge gas injecting operation (second purge operation), and the second plasma generating operation.

In addition, the above-mentioned “precursor injecting operation—first plasma generating operation—first purge operation—reducing gas injecting operation —second plasma generating operation—second purge operation” may be defined as one process cycle CY for forming the low-resistance metal thin film layer 110. Then, the above-described process cycle CY is repeated a plurality of times to deposit or stack a plurality of low-resistance metal thin film layers 110 as illustrated in FIG. 1. Accordingly, the electrode in which a plurality of low-resistance metal thin film layers 110 are stacked or the electrode 100 for the semiconductor device including a plurality of low-resistance metal thin film layers 110 is formed. In this case, the number of repetitions of the process cycle CY may be adjusted according to a target thickness of the electrode 100 to be formed.

In FIG. 1, each low-resistance metal thin film layer 110 is separately illustrated to distinguish thin film layers formed by a plurality of process cycles CY, but the plurality of low-resistance metal thin film layers 110 stacked may be integrally formed.

Hereinafter, each operation of the process cycle CY will be described in more detail. Here, for convenience of description, the “low-resistance metal thin film layer 110” formed by the above-described process cycle CY is abbreviated as a “metal thin film layer 110.”

In the operation of injecting the precursor, the precursor containing a low-resistance metal element is injected into a chamber in which the substrate S is loaded. That is, a material containing a low-resistance metal element is used as the precursor. Here, the low-resistance metal element may be at least one of molybdenum (Mo), ruthenium (Ru), and copper (Cu). That is, the precursor containing the low-resistance metal element may be a precursor containing at least one of molybdenum (Mo), ruthenium (Ru), and copper (Cu). Further, the “precursor containing a low-resistance metal element” may be referred to as “a source containing a low-resistance metal element”.

As the precursor containing molybdenum (Mo), for example, a material containing at least one of molybdenum hexacarbonyl and molybdenum pentachloride may be used.

For example, as the precursor source containing ruthenium (Ru), for example, a material containing ethylcyclopentadienyl ruthenium ((EtCp)₂Ru)(Bis(ethylcyclopentadienyl)ruthenium) may be used.

Further, as the precursor containing copper (Cu), for example, an organometallic compound or a material containing F or Cl may be used. As a more specific example, as the precursor source containing copper (Cu), which is an organometallic compound, for example, a material containing at least one of Cu(II)-2,2,6,6-tetramethyl-3,5-heptandionate [Cu(thd)₂] and Cu(II) hexafluoroacetylacetonate [Cu(hfac)₂] may be used. In addition, as the copper precursor source containing F or Cl, a material containing at least one of CuCl₁, CuCl₂, CuF₁, CuF₂, CuBr₁, CuBr₂, CuI₁ or CuI₂ may be used.

Further, the precursor containing at least one of molybdenum (Mo), ruthenium (Ru), and copper (Cu) may be in a solid state or a liquid state. Accordingly, the precursor in a solid or liquid state is heated before injecting to convert it into a gas, and then the precursor in a gaseous state is injected onto the substrate S. When the precursor is injected toward the substrate S, the precursor or the low-resistance metal element included in the precursor is adsorbed to the substrate S, whereby an adsorption layer 111 is formed on the substrate S as illustrated in (a) of FIG. 3. That is, the adsorption layer 111 or the thin film containing at least one of molybdenum (Mo), ruthenium (Ru), and copper (Cu) is formed.

When the precursor injecting operation is finished, purge gas is injected into the chamber for purging (first purge). At this time, for example, Ar gas may be used as the purge gas.

Meanwhile, in the precursor containing at least one of molybdenum (Mo), ruthenium (Ru) and copper (Cu), ligands of at least one of carbon (C), oxygen (O), and hydrogen (H) may be included depending on the type of material. That is, ligands of at least one of carbon (C), oxygen (O), and hydrogen (H) acting as impurities when the precursor containing at least one low-resistance metal element selected from molybdenum (Mo), ruthenium (Ru), and copper (Cu) is injected may be adsorbed. In addition, these ligands act as impurities that decrease the electrical characteristics of the electrode 100, for example, increase resistance.

Therefore, in accordance with the exemplary embodiment, after injecting the precursor, the reducing gas containing oxygen (O) or hydrogen (H) is injected to remove impurities derived from the precursor. In addition, after injecting the precursor and after injecting the reducing gas, hydrogen plasma or oxygen plasma is generated to remove impurities derived from the precursor.

The first plasma generating operation is an operation for removing impurities from the adsorption layer 111 and may be performed after the injection of the precursor is finished. More specifically, when the precursor injection is finished, a gas for generating plasma is injected toward the inside of the chamber or toward the substrate S, and power for generating the plasma is supplied. In this case, for example, radio frequency (RF) power is applied to at least one of the chamber, a susceptor on which the substrate S is seated in the chamber, and an injector for injecting gas into the chamber. In addition, the gas for generating plasma may be, for example, a gas containing hydrogen (H) or a gas containing oxygen (O). More specifically, the gas containing hydrogen (H) may be H₂ gas, and the gas containing oxygen (O) may be O₂ gas. When RF power is applied and the gas containing hydrogen (H) or oxygen (O) is injected in this way, plasma containing hydrogen or plasma containing oxygen may be generated inside the chamber. That is, hydrogen plasma or oxygen plasma may be generated. Accordingly, the substrate S or the substrate S on which the adsorption layer 111 is formed is exposed to the first plasma.

The generated hydrogen plasma or oxygen plasma reacts with the adsorption layer 111 adsorbed on the substrate and removes at least one of carbon (C), oxygen (O), and hydrogen (H) from the adsorption layer 111. That is, in a situation in which ligands of at least one of carbon (C), oxygen (O), and hydrogen (H) derived from the precursor are contained in the adsorption layer 111, when the hydrogen plasma or oxygen plasma reacts with the adsorption layer 111, the ligands are separated from the adsorption layer 111. That is, a ligand bond of at least one of carbon (C), oxygen (O), and hydrogen (H) contained in the precursor of the adsorption layer 111 is broken by the hydrogen plasma or the oxygen plasma and is separated from the adsorption layer 111. In other words, ligand impurities of at least one of carbon (C), oxygen (O), and hydrogen (H) are extracted from the adsorption layer 111 by the plasma. Accordingly, the content of ligand impurities of at least one of carbon (C), oxygen (O), and hydrogen (H) contained in the adsorption layer 111 may be reduced or removed.

The reducing gas injecting operation is performed after the first plasma generating operation is finished, and the reducing gas is injected toward the substrate S loaded into the chamber. Gas containing hydrogen (H) or oxygen (O) is used as the reducing gas, and as a more specific example, H₂ gas or O₂ gas may be used as the reducing gas.

Hereinafter, in order to distinguish the adsorption layer 111 formed by injecting the precursor onto the substrate S ((a) of FIG. 3) and the adsorption layer 111 exposed to the reducing gas or the adsorption layer 111 reacted with the reducing gas by injecting the reducing gas onto the substrate S on which the adsorption layer 111 is formed, the adsorption layer 111 exposed to the reducing gas or the adsorption layer 111 reacted with the reducing gas by injecting the reducing gas onto the substrate S on which the adsorption layer 111 is formed, is referred to as a “low-resistance metal thin film layer 110” or a “metal thin film layer 110”.

When reducing gas is injected toward the substrate S, the low-resistance metal thin film layer 110 (hereinafter referred to as the metal thin film layer 110) is formed as illustrated in (c) of FIG. 3. That is, the metal thin film layer 110 containing at least one of molybdenum (Mo), ruthenium (Ru), and copper (Cu) is formed.

In this case, hydrogen (H) or oxygen (O) contained in the reducing gas removes ligand impurities of at least one of carbon (C), oxygen (O), and hydrogen (H) remaining in the adsorption layer 111 or the metal thin film layer 110. That is, ligand impurities of at least one of carbon (C), oxygen (O), and hydrogen (H) that has not been removed in the first plasma generating operation may remain in the adsorption layer 111. The ligand impurities may be further removed by hydrogen (H) or oxygen (O) injected in the reducing gas injecting operation. In other words, the ligand bond of at least one of carbon (C), oxygen (O), and hydrogen (H) contained in the precursor of the adsorption layer 111 or the metal thin film layer 110 may be broken by hydrogen (H) or oxygen (O) contained in the reducing gas, and accordingly, the ligand impurities may be removed. Accordingly, the content of ligand impurities of at least one of carbon (C), oxygen (O), and hydrogen (H) contained in the metal thin film layer 110 may be reduced or removed.

A flow rate of the reducing gas injected in the reducing gas injecting operation may be injected in a larger amount than the gas injected in the first plasma generating operation described above and the second plasma generating operation described later. That is, in the flow rate of the gas containing hydrogen (H) or oxygen (O) injected, it is preferable to adjust the flow rate of gas injected in the reducing gas injecting operation to be higher than the flow rate of gas injected in the first and second plasma generating operations. Therefore, in terms of removing impurities, a relatively large number of impurities may be removed in the reducing gas injecting operation as compared to the first and second plasma generation operations.

In addition, the gas containing hydrogen (H) or oxygen (O) injected in the reducing gas injecting operation has a higher flow rate than the gas injected in the first and second plasma generating operations, but the flow rate thereof may be small enough not to oxidize the metal of the precursor.

The reducing gas as described above may be referred to as a gas for removing impurities.

When the reducing gas injecting operation is finished, purge gas is injected into the chamber for purging (second purge). At this time, the same gas as in the first purge may be used, and for example, Ar gas may be used as the purge gas.

Meanwhile, although impurities are removed from the metal thin film layer 110 by injecting the reducing gas, some impurities may remain in the metal thin film layer 110.

Therefore, impurities are further reduced by generating oxygen plasma or hydrogen plasma (second plasma generation) after injecting the reducing gas.

The second plasma generating operation is an operation for additionally removing impurities from the metal thin film layer 110, and may be performed after the injection of the reducing gas is finished. More specifically, the second plasma generating operation may be performed after the second purge is finished. In this case, the second plasma may be produced or generated in the same manner as the first plasma generating operation described above. That is, the gas for generating plasma containing hydrogen (H) or oxygen (O) is injected toward the substrate S, and RF power is applied. Thus, the hydrogen plasma or oxygen plasma is generated inside the chamber (see (d) of FIG. 3). Thus, the metal thin film layer 110 is exposed to the second plasma.

The generated hydrogen plasma or oxygen plasma reacts with the metal thin film layer 110 formed or deposited on the substrate S. In addition, ligand impurities of at least one of carbon (C), oxygen (O), and hydrogen (H) derived from the precursor are separated from the metal thin film layer 110 by reaction with the plasma. In other words, ligand impurities of at least one of carbon (C), oxygen (O), and hydrogen (H) are extracted from the metal thin film layer 110. Accordingly, the content of ligand impurities of at least one of carbon (C), oxygen (O), and hydrogen (H) contained in the metal thin film layer 110 may be reduced or removed.

Then, the process cycle CY including the above-described “precursor injecting operation—first purge operation—first plasma generating operation—reducing gas injecting operation—second purge operation—second plasma generating operation” is repeatedly performed a plurality of times. Accordingly, as illustrated in FIG. 1, a plurality of metal thin film layers 110 are stacked on the substrate S, and accordingly, the electrode 100 having a predetermined thickness is formed.

In the above, it has been described that the reducing gas is injected after the first plasma generating operation is finished. However, the process cycle CY is not limited thereto, and the operation of injecting the purge gas may be further performed between the first plasma generating operation and the reducing gas injecting operation.

A deposition apparatus in which the above-described “precursor injecting operation, first purge operation, first plasma generating operation, reducing gas injecting operation, second purge operation, and second plasma generating operation” is performed may be a deposition apparatus that injects the precursor or gas in a lateral direction of the substrate. That is, the deposition apparatus may include the chamber, the susceptor on which the substrate S is seated in the chamber, and an injector installed on a sidewall of the chamber to inject the precursor or gas toward the substrate S seated on the susceptor in the lateral direction of the susceptor. Further, the deposition apparatus may include a power supply for applying power for generating plasma, for example, RF power, to at least one of the chamber, the susceptor, and the injector. In addition, when such a deposition apparatus is used, precursors or gases are injected in the lateral direction of the substrate S and flow toward the substrate.

In the above, it has been described that the electrode 100 is formed using the deposition apparatus in which the injector is installed in the lateral direction of the susceptor to inject the precursors or gases in the lateral direction of the substrate S. However, the installation is not limited thereto, and the injector may be installed on an upper wall of the chamber to be located above the susceptor. When such a deposition apparatus is used, precursors or gases may be injected above the substrate S.

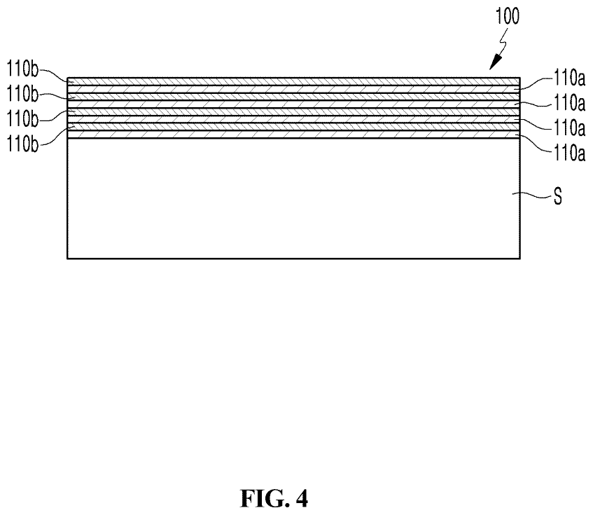

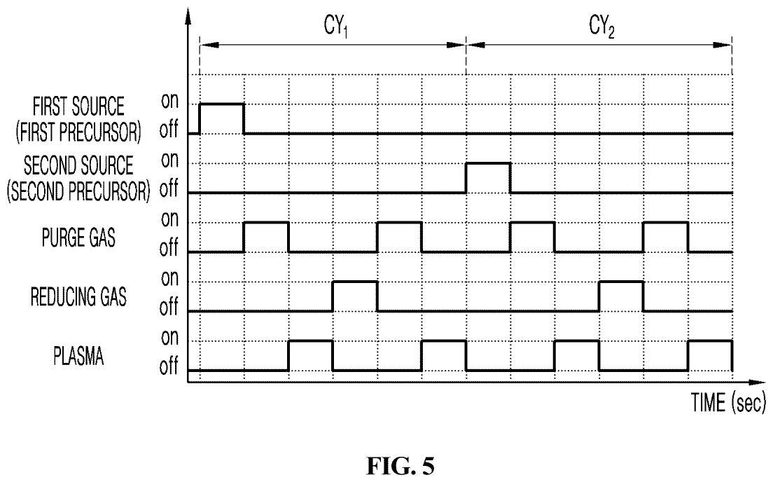

FIG. 4 is a view illustrating a state in which an electrode in accordance with another exemplary embodiment is formed on a substrate. FIG. 5 is a conceptual diagram for describing a method for forming an electrode by a method in accordance with the other exemplary embodiment.

Referring to FIG. 4, the electrode 100 in accordance with the other exemplary embodiment may include a first metal thin film layer 110a and a second metal thin film layer 110b, and the first metal thin film layer 110a and the second metal thin film layer 110b may be alternately stacked on each other. In this case, each of the first metal thin film layer 110a and the second metal thin film layer 110b may be a layer containing a low-resistance metal element. That is, each of the first metal thin film layer 110a and the second metal thin film layer 110b may be a layer containing at least one of molybdenum (Mo), ruthenium (Ru), and copper (Cu). In addition, the first metal thin film layer 110a and the second metal thin film layer 110b may be layers containing different low-resistance metal elements among molybdenum (Mo), ruthenium (Ru), and copper (Cu), or layers containing the same low-resistance metal element.

Here, the first metal thin film layer 110a and the second metal thin film layer 110b may be referred to as a “first low-resistance metal thin film layer 110a” and a “second low-resistance metal thin film layer 110b”, respectively.

Hereinafter, a method for forming an electrode on a substrate by the method in accordance with the other exemplary embodiment will be described with reference to FIGS. 4 and 5. In this case, a case in which the first metal thin film layer and the second metal thin film layer are formed of layers containing different low-resistance metal elements will be described as an example.

Referring to FIG. 5, a method of forming the electrode 100 includes a first process cycle CY₁ and a second process cycle CY₂.

The first process cycle CY₁ is a process cycle for forming the first metal thin film layer 110a. The first process cycle CY₁ may include a “first precursor injecting operation—first purge operation-first plasma generating operation—reducing gas injecting operation—second purge operation—second plasma generating operation.” Here, the first precursor may be referred to as a first source. The first precursor used in the first process cycle CY₁ may be a precursor containing at least one low-resistance metal element selected from among molybdenum (Mo), ruthenium (Ru), and copper (Cu). For example, the first precursor used in the first process cycle CY₁ may be a precursor containing molybdenum (Mo). Accordingly, the first metal thin film layer 110a containing molybdenum (Mo) may be formed by the first process cycle CY₁.

The second process cycle CY₂ is a process cycle for forming the second metal thin film layer 110b, and the second process cycle CY₂ may include a “second precursor injecting operation—first purge operation—first plasma generating operation—reducing gas injecting operation—second purge operation—second plasma generating operation.” Here, the second precursor may be referred to as a second source. In this case, the second precursor used in the second process cycle CY₂ may be a precursor that contains at least one low-resistance metal element selected from among molybdenum (Mo), ruthenium (Ru), and copper (Cu) and is different from the first precursor. For example, the second precursor used in the second process cycle CY₂ may be a precursor containing ruthenium (Ru). Accordingly, the second metal thin film layer 110b containing ruthenium (Ru) may be formed by the second process cycle CY₂.

In addition, the first process cycle CY₁ and the second process cycle CY₂ as described above are alternately repeated a plurality of times. Accordingly, as illustrated in FIG. 4, an electrode in which the first metal thin film layer 110a containing molybdenum (Mo) and the second metal thin film layer 110b containing ruthenium (Ru) are alternately stacked a plurality of times is formed.

In addition, each of the first and second process cycles CY₁ and CY₂ includes the first plasma generating operation, the reducing gas injecting operation, and the second plasma generating operation, as in the exemplary embodiment described above. That is, each of the first and second process cycles CY₁ and CY₂ may generate first plasma after the precursor injecting operation and generate second plasma after the reducing gas injecting operation, and the first plasma and the second plasma may be oxygen plasma or hydrogen plasma. In addition, each of the first process cycle CY₁ and the second process cycle CY₂ includes the reducing gas injecting operation performed between the first plasma generating operation and the second plasma generating operation, and a gas containing hydrogen (H) or oxygen (O) is used as the reducing gas.

Accordingly, it is possible to form the electrode 100 from which impurities due to the precursor containing the low-resistance metal element are removed. That is, by injecting the first precursor in the first process cycle CY₁ and then generating the hydrogen plasma or oxygen plasma in the first plasma generating operation, ligand impurities of at least one of carbon (C), oxygen (O), and hydrogen (H) may be removed from the first adsorption layer formed by adsorption of the first precursor on the substrate S. In addition, by injecting the reducing gas containing hydrogen (H) or oxygen (O) toward the substrate S on which the first adsorption layer is formed, ligand impurities of at least one of carbon (C), oxygen (O), and hydrogen (H) that has remained may be further removed. In addition, by injecting the reducing gas in the first process cycle CY₁ and then generating the hydrogen plasma or oxygen plasma in the second plasma generating operation, ligand impurities of at least one of carbon (C), oxygen (O), and hydrogen (H) may be further removed from the first metal thin film layer 110a.

In addition, even in the second process cycle CY₂, in each of the first plasma generating operation, the reducing gas injecting operation, and the second plasma generating operation, ligand impurities of at least one of carbon (C) and oxygen (O), and hydrogen (H) may be removed from the second adsorption layer and the second metal thin film layer 110b.

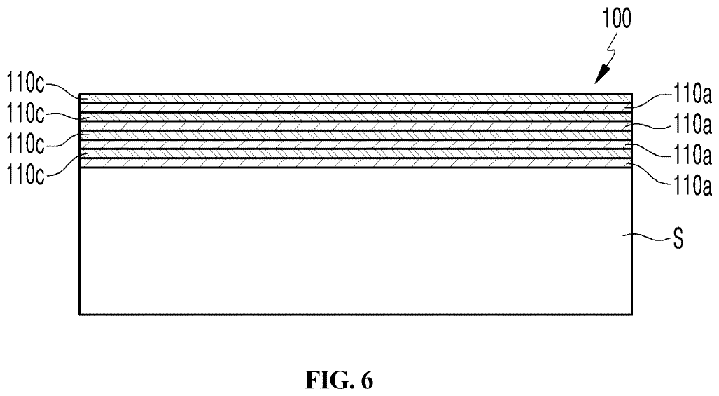

FIG. 6 is a view illustrating a state in which an electrode in accordance with a modified example of the exemplary embodiment is formed on a substrate.

In the above-described exemplary embodiment, it has been described that the electrode 100 is formed using the precursor containing at least one low-resistance metal element selected from among molybdenum (Mo), ruthenium (Ru), and copper (Cu) on the substrate. However, the formation of the electrode is not limited thereto and the electrode may be formed by alternately stacking metal thin film layers including another metal element in addition to the low-resistance metal element. That is, the electrode may be formed by alternately stacking a metal thin film layer containing a low-resistance metal element and a metal thin film layer containing an element other than the low-resistance metal element.

Hereinafter, an electrode in accordance with the modified example will be described. In this case, in order to differentiate the modified example from the exemplary embodiment and the other exemplary embodiment, in the modified example, the metal thin film layer containing the low-resistance metal element is referred to as a “first metal thin film layer 110a”, and the metal thin film layer containing the element other than the low-resistance metal element is referred to as a “third metal thin film layer 110c.” In addition, the cycle for forming the first metal thin film layer 110a containing the low-resistance metal element is referred to as a “first process cycle CY₁”, and the cycle for forming the third metal thin film layer 110c is referred to as a “third process cycle CY₃.”

Referring to FIG. 6, the electrode 100 in accordance with the modified example may include the first metal thin film layer 110a containing at least one low- resistance metal element among molybdenum (Mo), ruthenium (Ru), and copper (Cu) and the third metal thin film layer 110c containing titanium (Ti). Here, the third metal thin film layer 110c containing titanium (Ti) may be a TiN thin film layer. Further, as illustrated in FIG. 6, the electrode 100 may be formed by alternately stacking the first metal thin film layer 110a and the third metal thin film layer 110c a plurality of times. That is, the electrode 100 may include a plurality of first metal thin film layers 110a and a plurality of third metal thin film layers 110c and be formed by the alternately stacked first metal thin film layers 110a and third metal thin film layers 110c.

A process of forming the third metal thin film layer 110c containing titanium (Ti) may include an operation of injecting a source containing titanium (Ti) on the substrate S (source injecting operation), an operation of injecting a purge gas (first purge operation), an operation of injecting a reactance gas containing nitrogen (N) (reactant gas injecting operation), and an operation of injecting a purge gas (second purge operation).

In addition, the “operation of injecting the source containing titanium (Ti) —first purge operation—reactant gas injecting process—second purge process” may be defined as one third process cycle CY₃ for forming the third metal thin film layer 110c. Further, by alternately repeating the first process cycle CY₁ and the third process cycle CY₃ a plurality of times, the electrode 100 in which the first metal thin film layer 110a containing the low-resistance metal element and the third metal thin film layer 110c that is a TiN metal thin film layer are alternately stacked may be formed.

In addition, although not illustrated, the electrode 100 in accordance with the other exemplary embodiment, which is illustrated in FIG. 4, may be formed to include a TiN metal thin film layer. That is, the electrode 100 may be formed to include the first and second metal thin film layers 110a and 110b, which are low-resistance metal thin film layers, and the third metal thin film layer 110c, which is the TiN metal thin film layer. In this case, the electrode may be formed by alternately and repeatedly stacking the first metal thin film layer 110a, the second metal thin film layer 110b, and the third metal thin film layer 110c in this order.

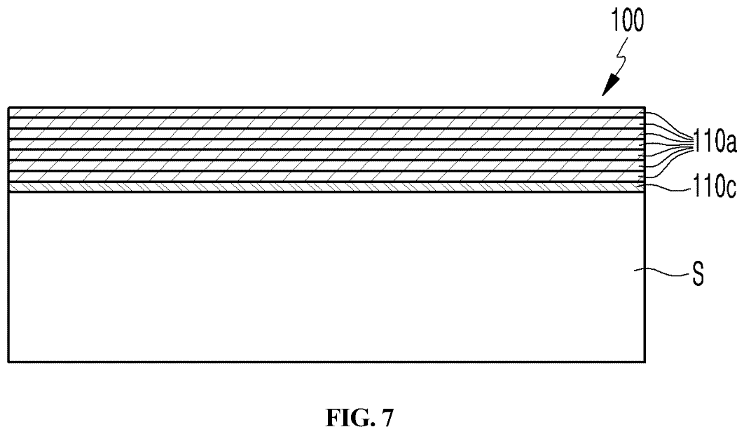

FIG. 7 is a view illustrating a state in which an electrode in accordance with another modified example of the exemplary embodiment is formed on a substrate.

In the above-described modified example, it has been described that the electrode 100 in which the first metal thin film layer 110a containing the low-resistance metal element and the third metal thin film layer 110c containing titanium (Ti) are alternately stacked is formed. However, the modified example of the exemplary embodiment is not limited thereto, and as in the other modified example shown in FIG. 7, the electrode 100 may be formed by preparing the substrate S having the third metal thin film layer 110c formed on an upper surface thereof, which is a metal thin film containing titanium (Ti), and forming a plurality of first low-resistance metal thin film layers 110a on the third metal thin film layer 110c. That is, the electrode 100 may be formed by preparing the substrate S having the metal thin film layer containing titanium (Ti), for example, the TiN thin film layer, formed on the upper surface thereof, and forming a plurality of first low-resistance metal thin film layers 110a on the TiN thin film layer.

As described above, in forming the electrode 100 in accordance with the exemplary embodiment, the other exemplary embodiment, the modified example, and the other modified example, the precursor containing the low-resistance metal element is injected, and then the reducing gas containing hydrogen (H) or oxygen (O) is injected. Accordingly, when the precursor is injected toward the substrate S, impurities adsorbed in the substrate S may be removed. That is, impurities may be removed from the adsorption layer 111 adsorbed on the substrate S by using the reducing gas to break the ligand bond of at least one of carbon (C), oxygen (O), and hydrogen (H) contained in the precursor.

In addition, the hydrogen plasma or oxygen plasma is generated between the operation of injecting the precursor containing the low-resistance metal element and the operation of injecting the reducing gas (generation of the first plasma), and the hydrogen plasma or oxygen plasma is generated after the reducing gas is injected (generation of the second plasma). Accordingly, ligand impurities of at least one of carbon (C), oxygen (O), and hydrogen (H) contained in the adsorption layer 111 may be removed by using the first plasma before the reducing gas is injected. In addition, after the reducing gas is injected, ligand impurities of at least one of carbon (C), oxygen (O), and hydrogen (H) contained in the metal thin film layer 110 may be further removed by using the second plasma.

Accordingly, the electrode 100 from which ligand impurities of at least one of carbon (C), oxygen (O), and hydrogen (H) derived from the precursor containing the low-resistance metal element are removed may be prepared. Accordingly, degradation of electrical characteristics of the electrode 100 due to impurities may be suppressed or prevented. That is, the electrode 100 having improved electrical characteristics, more specifically, the electrode 100 having lower resistance may be prepared.

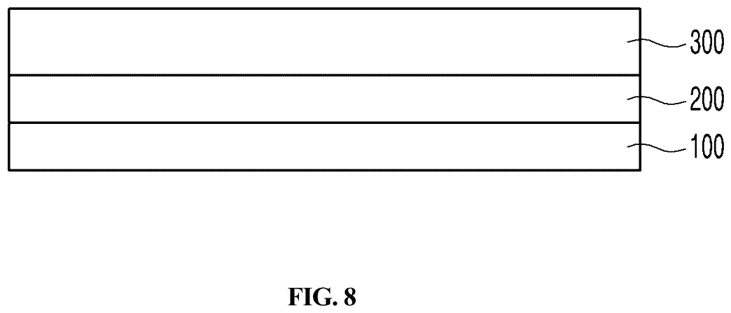

Hereinafter, an electrode for a semiconductor device and an electronic forming method for the semiconductor device in accordance with yet another exemplary embodiment will be described with reference to FIGS. 8 to 11.

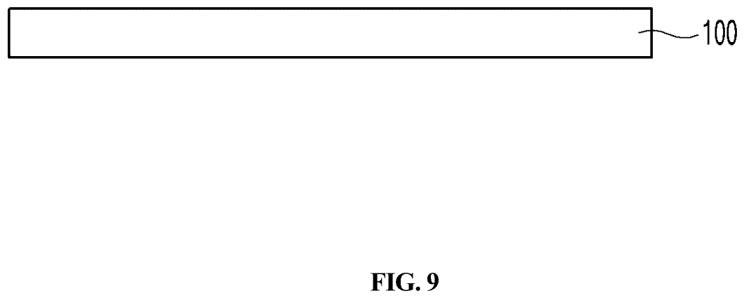

FIG. 8 is a view schematically illustrating a structure of a semiconductor device in accordance with yet another exemplary embodiment. FIGS. 9 to 11 exemplarily illustrate a method of forming the semiconductor device in accordance with the yet another exemplary embodiment.

Here, for convenience of description, in FIGS. 8 to 11, reference numerals are used separately from FIGS. 1, 3, 6, and 7 described above.

The yet another exemplary embodiment provides an electrode for a semiconductor device and a method for forming the same capable of reducing damage to a lower film occurring in a process of forming the electrode when the electrode is formed on a silicon film or silicon-containing film.

In addition, the yet another exemplary embodiment provides an electrode for a semiconductor device and a method for forming the same, the electrode includes a more improved barrier film for reducing damage to a lower film occurring in a process of forming the electrode when the electrode is formed on a silicon film or silicon-containing film.

Further, the yet another exemplary embodiment provides a more improved electrode for a semiconductor device and a method for forming the same capable of reducing damage to surface roughness of a lower film occurring in a process of forming the electrode when the electrode is formed on a silicon film or silicon-containing film.

In addition, the yet another exemplary embodiment provides a more improved electrode for a semiconductor device and a method for forming the same capable of reducing damage to surface roughness of a more improved barrier film for reducing damage to a lower film occurring in a process of forming the electrode when the electrode is formed on a silicon film or silicon-containing film.

The electrode of the semiconductor device in accordance with the yet another embodiment may be an electrode formed on an insulating film.

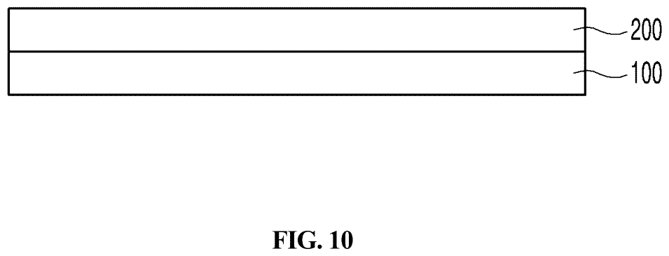

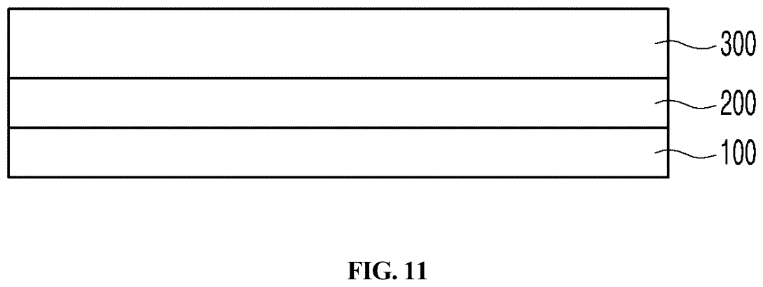

Referring to FIG. 9, a substrate (not illustrated) may be a substrate on which an insulating film 100 made of silicon film or a silicon-containing film is formed. Referring to FIG. 10, an operation of forming a ruthenium (Ru) film or a ruthenium (Ru)-containing film on the insulating film 100 as a barrier film on the substrate may be performed. Referring to FIG. 11, an operation of forming tungsten (W) or a tungsten (W)-containing film on the ruthenium (Ru) or the ruthenium (Ru) film-containing film may be performed.

The ruthenium (Ru) or ruthenium (Ru)-containing film may be formed by chemical vapor deposition (CVD), physical vapor deposition (PVD), or atomic layer deposition (ALD), but is not limited thereto.

In the yet another exemplary embodiment, the ruthenium (Ru) or ruthenium (Ru)-containing film may be formed by the atomic layer deposition (ALD). Specifically, the ruthenium (Ru) or ruthenium (Ru)-containing film may be formed by repeatedly performing a deposition cycle including an operation of injecting a source gas containing ruthenium (Ru) to the insulating film 100 on the substrate, an operation of purging the source gas, an operation of injecting a gas containing oxygen (O₂), and an operation of purging a gas containing oxygen. Using the atomic layer deposition method, deposition at a lower temperature is possible than the general chemical vapor deposition method (CVD), and the atomic layer deposition method may be advantageous when an ultra-thin film is formed.

It is preferable that the thickness of the ruthenium (Ru) film or the ruthenium (Ru)-containing film is 50% or less of the thickness of an electrode to be formed later. When the electrode is formed of a tungsten (W) film or a tungsten (W)-containing film, preferably, the thickness of the ruthenium (Ru) film or the ruthenium (Ru)-containing film is 50% or less of the thickness of the tungsten (W) film or the tungsten (W)-containing film. Specifically, the ruthenium (Ru) film or the ruthenium (Ru)-containing film is preferably formed to be a thickness of approximately 5 Å to 50 Å. When the deposition is made to a thickness of less than 5 Å, it is difficult to obtain an effect as the barrier film, and when ruthenium (Ru) is thickly deposited, exceeding 50 Å, expensive ruthenium (Ru) material is used thickly, resulting in high cost.

The ruthenium (Ru)-containing film may be a ruthenium oxide (RuO) film.

The ruthenium (Ru) or ruthenium (Ru)-containing film may be formed of an organic source containing ruthenium (Ru). When the barrier film is formed using a ruthenium (Ru) source containing the halogen element (fluorine or chlorine), the lower film may be damaged and the surface roughness of the lower film may deteriorate by the halogen element included in the ruthenium (Ru) source when ruthenium (Ru) is formed. When the ruthenium (Ru) or ruthenium (Ru)-containing film is formed as the organic source that does not contain the halogen element (fluorine or chlorine), the lower film may not be damaged.

Meanwhile, the ruthenium (Ru) or ruthenium (Ru)-containing film itself has strong resistance to the halogen element (fluorine or chlorine). When the electrode is formed in a later operation, the damage may be reduced even when the lower film is exposed to the gas for forming the electrode, and thus, improved barrier film characteristics compared to the existing titanium nitride film (TiN) may be obtained.

The tungsten (W) or tungsten (W)-containing film may be formed by chemical vapor deposition (CVD), physical vapor deposition (PVD), or atomic layer deposition, but is not limited thereto.

In the yet another exemplary embodiment, the tungsten (W) or tungsten (W)-containing film may be formed by the atomic layer deposition. For both ruthenium (Ru) and tungsten (W), a uniform film quality may be secured through the atomic layer deposition.

In addition, the tungsten (W) or tungsten (W)-containing film may be formed from a gaseous halogen gas such as tungsten hexafluoride (WF₆).

Meanwhile, the electrode for the semiconductor device in accordance with the yet another exemplary embodiment may be an electrode or wire of a memory or non-memory device. When an active layer of a transistor, which is the semiconductor device, is a silicon-containing film, a gate electrode, a source electrode, or a drain electrode of the transistor may be formed of silicon.

On the other hand, when the active layer of the transistor is a metal oxide semiconductor or a Group 3-5 semiconductor, the electrode for the semiconductor device in accordance with the exemplary embodiments may contain the ruthenium (Ru) or ruthenium-containing film between the electrode and the active layer. The electrode for the semiconductor device may contain the ruthenium (Ru) or ruthenium-containing film between the electrode and the active layer containing at least one of indium, gallium, zinc, and tin. The electrode for the semiconductor device may include the ruthenium (Ru) or ruthenium-containing film between the electrode and the active layer formed of GaN, GaAs, or the like.

Before forming the ruthenium (Ru) film or the ruthenium (Ru)-containing film, an operation of removing oxides or impurities from a surface of the silicon film or the silicon-containing film may be included. Accordingly, it is possible to, before forming the ruthenium (Ru), remove impurities present on the upper part of the lower film and remove the natural oxide film present in the lower film, and by forming the ruthenium (Ru) film or the ruthenium (Ru)-containing film in this way, it is possible to form a high-quality film

The structure in accordance with exemplary embodiments may include the insulating film 100, the ruthenium (Ru) film 200, and the tungsten (W) film 300. At least one of a bit line 160 and a word line 120 may be formed on an upper part or lower part of the structure.

Schematically describing the electrode forming method for the semiconductor device in accordance with the yet another exemplary embodiment, the electrode forming method may include forming a ruthenium film or a ruthenium-containing film on a silicon film or silicon-containing film and forming a tungsten-containing film on the ruthenium film or the ruthenium-containing film.

A thickness of the ruthenium film or the ruthenium-containing film may be formed to be a thickness of 50% or less of a thickness of the tungsten-containing film.

The ruthenium film or the ruthenium-containing film may be formed to be a thickness of approximately 5 Å to 50 Å.

The ruthenium film or ruthenium-containing film may be formed by an atomic layer deposition method.

The ruthenium film or ruthenium-containing film may be formed of an organic source containing ruthenium. The tungsten-containing film may be formed of a tungsten halogen gas. The electrode may form a semiconductor device of any one of an electrode of a memory device, a word line, a bit line, an electrode of a transistor, an electrode of a GaN semiconductor, and an electrode of a GaAs semiconductor.

In accordance with the exemplary embodiments, a reducing gas is injected after a precursor containing a low-resistance metal element is injected. In addition, hydrogen plasma or oxygen plasma is generated before and after the reducing gas is injected.

Accordingly, it is possible to provide an electrode from which ligand impurities derived from a precursor containing a low-resistance metal element are removed. Therefore, it is possible to provide an electrode with low resistance.

Further, in accordance with the exemplary embodiments, it is possible to form a barrier film and an electrode to reduce damage of a lower film.

In the above, although preferred embodiments of the present disclosure have been described and illustrated using specific terms, such terms are only used to clearly describe the present disclosure, and it is obvious that various modifications and changes can be made to the embodiments of the present disclosure and the described terms without departing from the spirit and scope of the present disclosure as defined by the following claims and their equivalents. Such modified embodiments should not be individually understood from the spirit and scope of the present disclosure, and should be construed as falling within the scope of the claims of the present disclosure.

1. An electrode forming method for a semiconductor device, comprising:
preparing a substrate;
injecting a precursor containing a low-resistance metal element onto the substrate; and
forming a low-resistance metal thin film layer by injecting a gas containing hydrogen (H) or oxygen (O) onto the substrate.

2. The electrode forming method of claim 1, wherein the injecting of the precursor and the forming of the low-resistance metal thin film layer are sequentially performed a plurality of times.

3. The electrode forming method of claim 2, further comprising:
exposing the substrate to a first plasma to remove impurities adsorbed on the substrate after the injecting of the precursor; and
exposing the low-resistance metal thin film layer to a second plasma to remove impurities after the forming of the low-resistance metal thin film layer,
wherein the injecting of the precursor, the exposing to the first plasma, and the exposing to the second plasma are sequentially performed a plurality of times.

4. The electrode forming method of claim 1, wherein the low-resistance metal element includes at least one of molybdenum (Mo), ruthenium (Ru), and copper (Cu).

5. The electrode forming method of claim 3, wherein the first plasma is formed of plasma containing hydrogen (H) or plasma containing oxygen (O).

6. The electrode forming method of claim 3, wherein the second plasma is formed of plasma containing hydrogen (H) or plasma containing oxygen (O).

7. The electrode forming method of claim 1, further comprising forming a TiN thin film layer on the substrate,
wherein the forming of the TiN thin film layer comprises:
injecting a source containing titanium (Ti) on the substrate; and
injecting a gas containing nitrogen (N) on the substrate, and
the injecting of the precursor containing the low-resistance metal element, the forming of the low-resistance metal thin film layer, and the forming of the TiN thin film layer are sequentially performed a plurality of times.

8. The electrode forming method of claim 1, wherein in the preparing of the substrate, a substrate having an upper surface on which a TiN thin film layer is formed is prepared.

9. An electrode forming method for a semiconductor device, comprising:
preparing a substrate;
forming a first low-resistance metal thin film layer by injecting a source containing a first low-resistance metal element and injecting a gas containing hydrogen (H) or oxygen (O); and
forming a second low-resistance metal thin film layer by injecting a source containing a second low-resistance metal element and injecting a gas containing hydrogen (H) or oxygen (O),
wherein the forming of the first low-resistance metal thin film layer and the forming of the second low-resistance metal thin film layer are sequentially performed a plurality of times.

10. The electrode forming method of claim 9, wherein the first low-resistance metal element and the second low-resistance metal element contain at least one of molybdenum (Mo), ruthenium (Ru), and copper (Cu).

11. The electrode forming method of claim 9, wherein the first low-resistance metal element and the second low-resistance metal element contain the same metal element.

12. The electrode forming method of claim 9, wherein at least one of the first low-resistance metal element and the second low-resistance metal element contain two or more of molybdenum (Mo), ruthenium (Ru), and copper (Cu).

13. The electrode forming method of claim 9, further comprising forming a TiN thin film layer by injecting a source containing titanium (Ti) and injecting a reactant containing nitrogen (N),
wherein the forming of the first low-resistance metal thin film layer, the forming of the second low-resistance metal thin film layer, and the forming of the TiN thin film layer are sequentially and repeatedly performed.

14. The electrode forming method of claim 9, wherein in the preparing of the substrate, a substrate having an upper surface on which a TiN thin film layer is formed is prepared.

15. An electrode forming method for a semiconductor device, comprising:
preparing a substrate;
injecting a liquid precursor containing a low-resistance metal element onto the substrate; and
forming a low-resistance metal thin film layer by injecting a gas containing hydrogen (H) or oxygen (O) onto the substrate.

16. The electrode forming method of claim 15, wherein the injecting of the precursor and the forming of the low-resistance metal thin film layer are sequentially performed a plurality of times.

17. The electrode forming method of claim 15, wherein the low-resistance metal element includes at least one of molybdenum (Mo), ruthenium (Ru), and copper (Cu).

18-32. (canceled)
